(19) United States
(12) Patent Application Publication
(10) Pub. No.: US 2015/0192614 A1
(43) Pub. Date: Jul. 9, 2015

(54) CANTILEVER CONTACT PROBE FOR A TESTING HEAD

(71) Applicant: Technoprobe S.p.A., Cernusco Lombardone (IT)

(72) Inventors: Riccardo Vettori, Cernusco Lombardone (IT); Emanuele Bertarelli, Cernusco Lombardone (IT); Marco Diegidio, Cernusco Lombardone (IT)

(21) Appl. No.: 14/638,533

(22) Filed: Mar. 4, 2015

Related U.S. Application Data
(63) Continuation-in-part of application No. PCT/EP2013/003587, filed on Nov. 27, 2013.

(30) Foreign Application Priority Data
Nov. 28, 2012 (IT) MI2012A002023

(51) Int. Cl. G01R 1/067; G01R 1/04; G01R 1/073

(52) U.S. Cl. CPC G01R 1/06727; G01R 1/07342; G01R 1/04

(57) ABSTRACT

A cantilever contact probe comprises at least a probe body and a hook-shaped end portion, being joined to the probe body and ending with a slanted section being configured as a hook. The end portion is bent at a bending point having a suitable inclination of the hooked slanted section with respect to a longitudinal extension axis of the probe and ends with a contact tip being able to assure a mechanical and electrical contact with a contact pad of a device under test. Suitably, the probe comprises at least a reduced portion having a first area with at least a first size being smaller than a corresponding first size of a second area of the probe in a section which does not comprise the reduced portion, along a side by side placing direction of the probes within a testing head. The reduced portion is substantially reduced along its sides thus forming an area having a reduced cross size being placed edgeways.

### BACKGROUND

### Technical Field

The present disclosure refers to a cantilever contact probe for a testing head.

### DESCRIPTION OF THE RELATED ART

As is known, a testing head is a device for electrically connecting a plurality of contact pads of a micro-structure (such as an integrated circuit or generally an electronic device) to corresponding channels of a testing apparatus or machine for testing the micro-structure.

The test, which is performed on integrated circuits, allows the detection and insulation of defective circuits, yet in the production phase. Normally, testing heads are therefore used for electrical testing of wafer based electrical circuits, prior to cutting and assembling the same inside a chip containment package.

It is therefore known that the efficiency and reliability of a measuring test relies, among other things, on the provision of a good electrical connection between the microstructure, or in general a device under test, and testing apparatus, and therefore, an optimal electrical contact between probe and pad.

It is also known that the electrical connection testing apparatus/device and hence probe/pad, though originally good, may with time undergo a substantial degradation and possibly vanish, because of dirt deposits and oxide formation on the contact pads of the device under test.

For ensuring the reliability and efficiency of a measuring test, it is therefore necessary to provide a “cleaning” of said contact pads.

Among the testing heads used in this particular technical field, for testing integrated circuits, the so called cantilever probe testing heads, which are provided with cantilevered probes, similar to fishing rods suspended over the device under test, are widely used.

In particular, a cantilever testing head of the known type usually supports a plurality of flexible, generally rod-like probes, having predetermined electrical and mechanical properties. The probes, which protrude from the cantilever testing head, have a substantially hook-shaped form, because of an end section having an elbow bend with an inner obtuse angle.

In particular, as schematically shown in FIGS. 1A and 1B, a testing head 1 having cantilevered probes usually comprises a supporting ring 2, made of aluminum, ceramics or other suitable material, which is usually coupled to a support 3 made of resin, able to include a plurality of movable contact elements or contact probes 4, which are usually composed of special alloy wires, with good electrical and mechanical properties, which protrude from the resin support 3 at a plurality of points 5 forming a suitable angle with a plane of the device under test 8, which is usually called body angle, schematically shown by 13 in the figure of the drawing. Such probes are commonly called cantilever probes.

In particular, the contact probes 4 have a hook-shaped end portion 4A bent to a suitable angle α with respect to the axis XX of the probes and ending with a contact tip 6, which is able to contact a plurality of contact pads 7 of a device under test 8.

The portion of the contact probes 4 outside the supporting ring 2 is usually welded to a printed circuit or board 9, as shown in FIG. 1B, in order to provide an electric contact between the testing head 1 with the cantilever probes and the test apparatus.

A good connection between the contact probes 4 of the testing head 1 and the contact pads 7 of the device under test 8 is ensured by a pressure of the testing head 1 against the same device, wherein the contact probes 4 are subject to a vertical bending directed in an opposite direction with respect to the movement of the device towards the head.

As schematically shown in FIG. 2A, with reference to a single contact probe 4, when device under test 8 moves vertically against the hook-shaped end portion 4A (as shown by the arrows FF in this figure), the contact probe 4 bends and its bending point, labeled as PG, which is the intersection between the hook-shaped end portion 4A and a probe section protruding with respect to the resin support 3, labeled as 4B, travels along a circular arc.

The protruding section 4B of the probe forms a working arm for the contact probe 4 during its vertical bending movement, and is usually called “free length”.

The hook-like shape of the contact probes 4 is such that during contact with the contact pads 7 of the device under test 8 and their upward travel or “overtravel” beyond the predetermined contact location, the contact tips 6 of the probes 4 slide over the contact pads 7 in the direction defined by the system geometry.

It is to be noted that the force caused by each contact probe 4 on the contact pads 7 is a function of various factors, wherein the main factors are the type of material making the probe, its shape, the angle α of its hook-shaped end portion 4A, the length of its protruding section or free length 4B and the overtravel of the pads 7 of the device under test 8. Such factors also define the sliding length of the contact tips 6 over the contact pads 7, which is commonly known a “scrub”.

In fact, such a sliding movement corresponds to a “scrubbing” or “brushing” of the surface of the contact pad 7, causing the removal of a layer of dirt or oxide which may be present on the same.

The sliding movement or scrubbing of the contact tips 6 over the pads 7 allows a durable and optimal electrical contact between the probes 4 and the pads 7 of the device under test 8.

In particular it is important to ensure a sufficient scrub of the contact tips on the contact pads 7, allowing a surface “cleaning” of same pads, improving the contact realized by the testing head 1.

This technique, though advantageous for the application on integrated circuits of the type being commonly used until recently, notoriously has a major technical drawback in case of cleaning recently designed integrated circuits. In fact, integrated circuits (and similar micro-structures) designed and manufactured in recent times have increasing densities of the contact pads, and decreasing pad sizes.

In particular, the desire to obtain a sufficient scrub of the contact pads 7 in order to ensure an electrical contact with the device under test 8, in all operating conditions of the testing head 1, contrasts with the current desire by the market to design increasingly denser devices, with contact pads 7 whose size is more and more decreasing. The movement of the contact tips 6 of the probes 4 over the contact pads 7 which allows a sufficient scrub is such that, in devices having pads with reduced sizes, there is a risk of the contact tip 6 to cross the boundaries of the same pad 7, not ensuring an electrical connection with the device under test 8, and possibly damaging the probe 4 or the device 8 itself.

The movement of the tips over the pads causes an incision of the latter and gives rise to incision marks which are usually called “scrub marks”.

A low value of scrub mark is indicative of a low invasiveness of a test, thus reducing damages to the contact pads 7 caused by the tips of the contact probes 4, and this in turn allows for a good quality of the following connection (bonding) with such pads.

It is therefore desirable to provide contact probes 4 which generate the smallest possible scrub marks.

Known testing heads also have intrinsic limits regarding the distance between two adjacent or contiguous probes, i.e. the center-to-center distance between two adjacent contact pads 7 of the device under test 8, indicated as “pitch” in the field. In particular, the minimum value of “pitch” of the pads which may be tested varies according to the geometric conditions and the size of the probes. In order to avoid that contiguous probes contact each other, the testing head 1 has to comply with the following relationship:

PL>fc+S

wherein:

PL is the distance between the contact tips of adjacent contact probes;

fc is the diameter of the contact probes 4; and

S is the safety distance between adjacent contact probes 4.

Condition S−0, i.e. a safety distance equal to zero, corresponds to the probes colliding.

It is to be noted that the diameter fc of the contact probes 4 is usually taken into account, since such probes are normally formed by metal wires with a circular cross section. More generally, the probe's diameter is understood as the maximum dimension of its section perpendicular to a longitudinal extension axis of the same probe, which, according to the previous definitions, is considered as extending along the side by side placing direction of the probes, i.e. where they can contact each other.

According to the current technologies, in order to increase the number of probes, with a same pitch value, it is known to reduce the size of the contact probes 4, in particular their diameter fc, causing a weakening of the same. Such a solution is therefore applicable in a limited number of cases only.

It is also known that, with high density contact pads 7, the contact probes 4 are positioned over multiple levels or layers, therefore varying the lengths L1, . . . Ln of the hook-shaped end portions 4A, as schematically shown in FIG. 2B.

The number N of levels for positioning a plurality of contact probes 4 having diameter fc over contact pads 7 having distance or pitch equal P, ensuring a safety distance S between each other, is calculated according to the following empirical formula:

N=(fc+S)/P (rounded to the next higher integer).

In case of testing heads having cantilever contact probes 4 positioned on multiple levels, the problem caused by collision of probes has evidently a three-dimensional character. In particular, the sites with the greatest risk of contact are the bending points PG of a probe at a level corresponding to a slightly tapered area of the hook-shaped end portion 4A of adjacent contact probes 4.

It is therefore advantageous, if possible, to position the contact probes 4 on a minimum number of levels.

The choice of the positioning arrangement of the contact probes 4 over multiple levels depends on various factors, among which the most important are the following:
available space for the contact probes 4 as a whole;
diameter fc of each contact probe 4;
shape of the hook-shaped end portions 4A; and
pitch of the device under test 8.

Considering a fixed pitch value for the device under test 8, it is possible to increase the number of probes housed on each level by reducing their diameter.

However it is to be noted that the contact probes 4 having a small diameter have a lower mechanical and electrical performance, due to the increase of the contact resistance between hooks and pads of the device under test 8, because of the lower pressure which is applied by the tips of the contact probes 4 on the respective contact pads 7.

It can be easily shown that also the length of the scrub marks is heavily influenced by the hook's length. An increase of the number N of levels, which causes an increase of the hook's length, causes also an increase of the associated scrub marks.

In particular, in a testing head having contact probes 4 on N levels, the probe of level 11, having a hook length of L1, produces a shorter scrub mark with respect to the probe at level 12, having a hook length L2, which in turn is shorter than the one generated by the probe on level 13, having a hook length L3.

The probe belonging to the higher level, ln, having a longest hook, Ln, will therefore create a longest scrub mark and will consequently inflict the maximum damage to the contact pads 7.

The desire of placing the probes on multiple levels contrasts the desire of limiting or even reducing the length of the scrub marks, i.e. the damage caused to the contact pads and the risk of crossing their borders, even more so because the size of the contact pads is steadily decreasing.

Moreover, by increasing the levels, the collision risk among the probes on higher levels is also increased, because their minimum mutual distance is also decreased, due to the conical shape of the probes.

As will become apparent from the above description, there are contrasting desires which suggest very precarious compromises to be made, and which severely compromise a good functionality of the testing head according to the prior art.

### BRIEF SUMMARY

An embodiment of the present disclosure is directed to a cantilever contact probe with an arrangement such as to reduce the probability of a contact even in a device under test having a reduced pitch, to increase the safety distance between probes and to reduce the scrub of the tips over the contact pads, at the same time ensuring a proper mechanical and electrical contact between the probes and the contact pads.

The arrangement of the contact probes is modified in at least a portion of their probe body, reducing the thickness of said body along a side by side placing direction of the probes.

The cantilever contact probe may comprise at least a probe body and a hook-shaped end portion, being joined to the probe body and ending with a slanted section, being configured as a hook, the end portion being bent at a bending point having a suitable inclination of the hooked slanted section with respect to a longitudinal extension axis of the probe and ending with a contact tip being able to ensure a mechanical and electrical contact with a contact pad of a device under test, characterized in that it comprises at least a reduced portion having a first area with at least a first size being smaller than a corresponding first size of a second area of the probe in a section which does not comprise the reduced portion, along a side by side placing direction of the probes within a testing head, the reduced portion being substantially reduced along its sides, thus forming an area having a reduced cross size being placed edgeways.

According to an aspect of the disclosure, the ratio between the first size of the first area at the reduced portion and the size of the second area may be chosen in the range 0.30-0.95.

According to another aspect of the disclosure, the reduced portion may be symmetrical with respect to the longitudinal extension axis of the probe.

Moreover, according to an aspect of the disclosure, the first area of the probe at the reduced portion has a second size along the orthogonal direction with respect to the side by side placing direction of the probes which is greater than the first size.

According to another aspect of the disclosure, the contact tip may comprise a corrugated contact portion.

Moreover, the reduced portion may be provided in a section of the probe body adjoining the end portion.

The reduced portion may also be provided in a section of the end portion at the bending point.

According to an aspect of the disclosure, the probe may comprise a reduced portion provided in a section of the probe body adjoining the end portion and a further reduced portion provided in a section of the end portion at the bending point.

According to another aspect of the disclosure, the value of the first size of the first area at the reduced portion may be chosen according to a value of a distance between the centers of the contact pads of the device under test.

Moreover, according to another aspect of the disclosure, the value of the second size of the first section at the reduced portion may be chosen according to a current that the probe should sustain.

According to a further aspect of the disclosure, the values of first and second sizes of the first area at the reduced portion may be chosen to control the contact force of the probe onto a contact pad of the device under test or to balance probes having slanted sections of different length or to contact pads being internal to the device.

The value of the first size of the first area at the reduced portion may vary between 25 μm and 200 μm and the value of the first size of the second area may vary between 50 μm and 300 μm. Alternatively, the value of the first size of the first area at the reduced portion may vary between 20 μm and 180 μm and the value of the first size of the second area may vary between 30 μm and 200 μnm. Moreover, the value of the second size of the first area at the reduced portion may vary between 50 μm and 400 μm.

According to another aspect of the disclosure, the first area at the reduced portion may have a shape chosen between a substantially quadrilateral figure which comprises two opposed rectilinear sides and two opposed curvilinear sides, a rectangle, a square, and an ellipse.

The technical problem is also solved by a testing head comprising at least a ring support, which is jointly coupled to a further resin support being able to include a plurality of cantilever contact probes according to the preceding aspects.

According to an aspect of the disclosure, the testing head may comprise at least a first level of contact probes having at least a reduced portion provided in a section of the end portion at the bending point and a second level of contact probes devoid of the reduced portion.

The characteristics and advantages of the contact probe and f the testing head according to the disclosure will be provided in the following description of their embodiments, provided as illustrative and non-limiting examples, with reference to annexed drawings.

### BRIEF DESCRIPTION OF THE DRAWINGS

FIG. 1A is a view from above of a testing head with cantilever probes according to the prior art,

FIG. 1B is a front sectional view of the testing head with cantilever probes of FIG. 1A,

FIG. 2A is a sectional view of a detail of the testing head with cantilever probes of FIG. 1A,

FIG. 2B is a sectional view of a detail of another embodiment of a testing head with cantilever probes according to the prior art,

FIG. 3A is a perspective view of a cantilever contact probe according to the prior art,

FIG. 3B is a sectional transversal view of a cantilever contact probe of FIG. 3A,

FIG. 4A is a perspective view of a cantilever contact probe according to an embodiment of the disclosure,

FIGS. 4B and 4C are sectional views of the cantilever contact probe of FIG. 4A,

FIG. 5A is a perspective view of a testing head including cantilever contact probes according to FIG. 4A,

FIG. 5B is a view from above of a detail of the testing head of FIG. 5A, comparing known cantilever contact probes according to FIG. 3A and cantilever contact probes according to the embodiment of the disclosure of FIG. 4A,

FIG. 6 is a perspective view of a cantilever contact probe according to an alternative embodiment of the disclosure,

FIG. 7 is a perspective view of a testing head including cantilever contact probes according to FIG. 6,

FIGS. 7A and 7B are a front view of a detail of a testing head of FIG. 7, comparing known cantilever contact probes of FIG. 3A and cantilever contact probes according to the alternative embodiment of the disclosure of FIG. 6, respectively,

FIG. 8 is a perspective view of a cantilever contact probe according to a further alternative embodiment of the disclosure, and

FIGS. 9A-9E are cross sections of cantilever contact probes according to alternative embodiments of the disclosure.

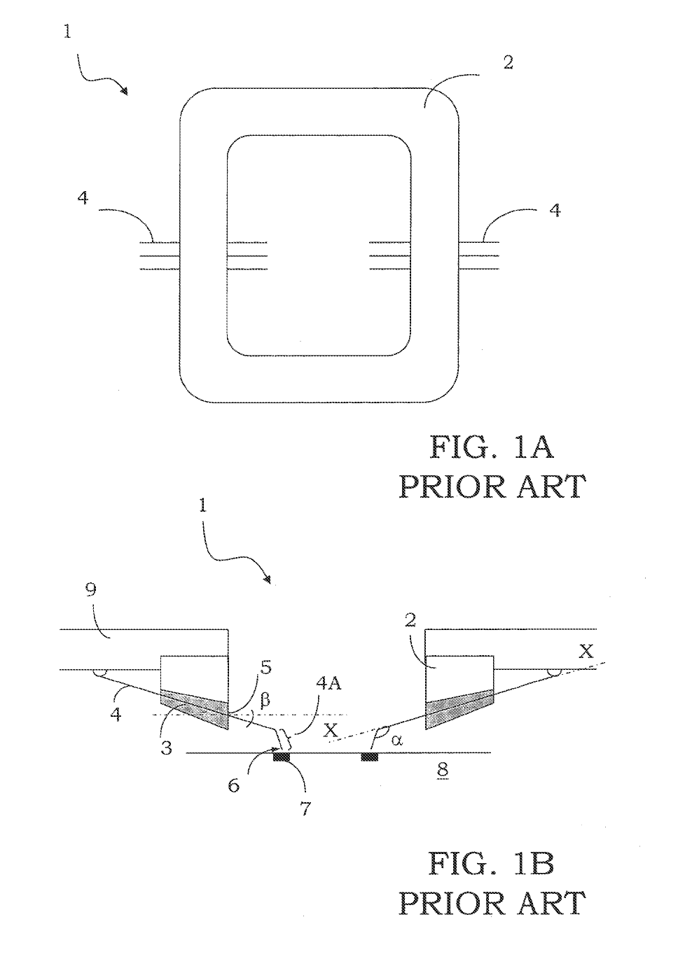

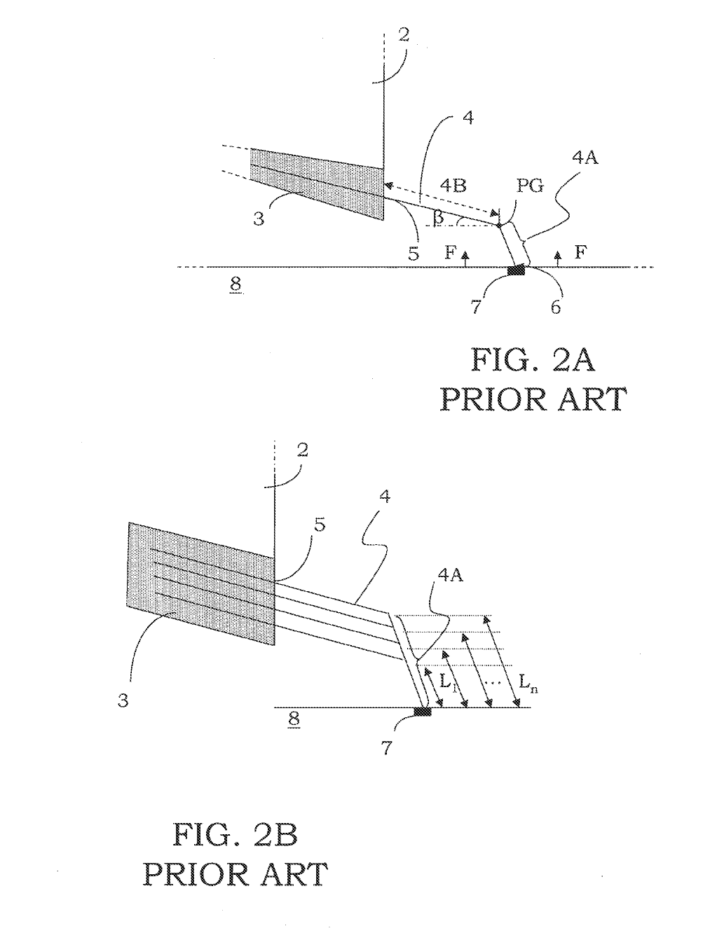

### DETAILED DESCRIPTION

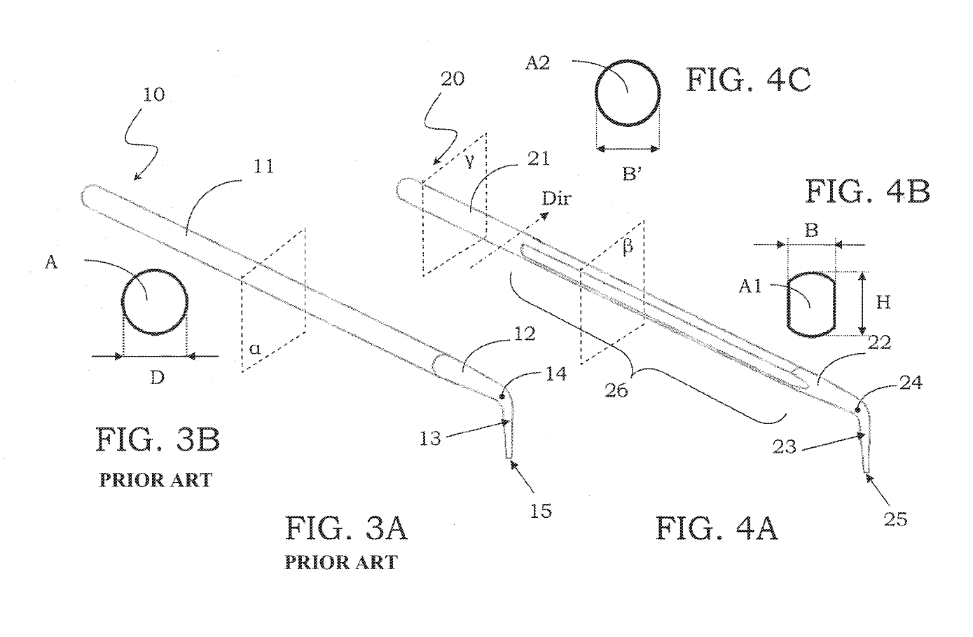

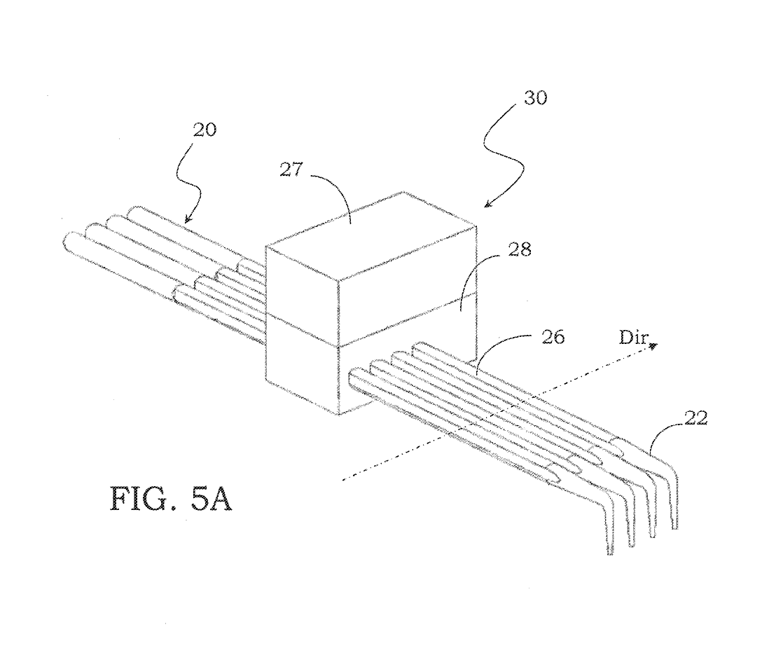

With particular reference to FIGS. 3A and 4A, a cantilever contact probe according to the prior art (FIG. 3A) and a cantilever contact probe according to an embodiment of the disclosure (FIG. 4A) are schematically shown.

In particular, the cantilever contact probe 10 according to the prior art, shown in FIG. 3A, comprises a probe body 11 and an end portion 12, joined to the probe body 11 and ending with a slanted section 13, in a hook-shaped arrangement. As already said, the end portion 12 is bent at a bending point 14 with a suitable inclination of the slanted section 13 with respect to the axis of the probe body 11, and it ends with a contact tip 15, for contacting a plurality of contact pads 7 of a device under test.

The probe body 11 has a rod-like shape, having a substantially constant sectional area with a circular shape of diameter D, as schematically shown in FIG. 3B, which shows a cross section of said probe body 11 at a transversal plane α as shown in FIG. 3A.

Usually, for a probe having a total length between 3.8 and 8 cm, the length of the probe body 11 varies between 3.7 cm and 7.7 cm and the length of the hook-shaped end portion 12 varies between 1 mm and 3 mm, wherein the length of the slanted section 13 may vary between 0.15 mm and 1.5 mm. Furthermore, the diameter D of probe body 11 may vary between 50 μm and 300 μm, whereas the diameter d of contact tip 15, which is also substantially circular, may vary between 8 μm and 80 μm. In this way, the hook-shaped end portion 12 has a tapered frustoconical shape.

A cantilever contact probe according to an embodiment of the disclosure shown in FIG. 4A, generally indicated in 20, comprises a probe body 21 and an end portion 22, joined to the probe body 21 and ending with a slanted hook-shaped section 23. The end portion 22 is bent at a bending point 24 with a suitable inclination of the slanted hook-shaped section 23, with respect to a longitudinal extension axis of the probe body 21, and ending with a contact tip 25, for contacting a plurality of contact pads 7 of a device under test.

Advantageously, according to an embodiment of the disclosure, the cantilever contact probe 20 comprises at least a reduced portion 26 having an area with at least a first size smaller than a corresponding first size of the area of the rest of the probe, in particular along the side by side placing direction of the probes inside a testing head, labeled as Dir in FIG. 4A. More in particular, such reduced portion is reduced on the sides, forming an area of reduced cross size positioned edgeways, wherein such probes are positioned, as will be made clear in the following, in such a way as to protrude from a supporting ring on at least one level, intended to be the height of the point where the probes protrude from the supporting ring, or more precisely from the resin support associated to the same, with respect to a device under test, in a side by side arrangement of same probes. The probes on a given level may be considered as placed side by side along a plane, which we call probe plane, at a certain distance from a defined plane of the device under test, when the testing head comprising such probes is in contact and pressing on the same, wherein each level corresponds to a different distance between the probe plane and the plane of the device under test.

In the embodiment of FIG. 4A, the cantilever contact probe 20 has a reduced portion 26, which is in particular provided in a section of the probe body 21 adjoining the end portion 22, having a first area A1 shown in FIG. 4B, taken in correspondence of a first transversal plane β of FIG. 4A with a first size B, in particular, a maximum size in the side by side direction of the probes Dir, and a second size H, in particular, a maximum size in a direction perpendicular to the side by side direction of the probes Dir. In essence, the first size B is the thickness of the reduced portion 26 of the cantilever contact probe 20 and the second size H is its height. In a preferred embodiment, the second size H is greater than the first size B.

The cantilever contact probe 20 also has a second area A2 shown in FIG. 4C, taken in correspondence of a second transversal plane γ in FIG. 4A, therefore corresponding to the probe body 21, where the reduced portion 26 is absent, the area A2 being circular with a diameter B′, which in the example shown is equal to the area A of the cantilever contact probe 10 of FIG. 3A.

The reduced portion 26 may be provided by suitable working of the cantilever contact probe 20, for example by removing material in a symmetrical fashion with respect to the longitudinal extension axis of the cantilever contact probe 20, from a section of the probe body 21, providing a sort of symmetrical recess in that section.

Advantageously, according to an embodiment of the disclosure, the first size B of the first area A1, taken in correspondence of the reduced portion 26, is smaller than the first size B′ of the second area A2, taken in correspondence of the section of the probe body 21 lacking the reduced portion 26, along the same side by side direction of the probes Dir, and transversally with respect to the probe body 21. In a preferred embodiment, the second area A2 has a circular shape with a diameter B′, and the second size H of the first area A1 is equal to said diameter B′.

In a further preferred embodiment, the first size B of the first area A1 of the reduced portion 26 is equal to even 20% of the first size B′ of the second area A2 along the same side by side placing direction of the probes Dir. In general, the ratio between the first size B of the first area A1 and the first size B′ of the second area is chosen between 0.30 and 0.95.

The hook-shaped end portion 22 of each cantilever contact probe 20 ends with a contact tip 25, wherein such tip is such as to abut against and contact a plurality of contact pads of a device under test.

It has to be noted that the provision of the reduced portion 26 in the probe body 21 alters the elastic properties of the cantilever contact probe 20 as a whole, and in particular of the probe body 21, and allows a reduction of the number of levels at which the probes have to be positioned.

For a probe with a total length varying between 3.8 cm and 8 cm, the length of the probe body 21 varies between 3.7 cm and 7.7 cm, and the length of the hook-shaped end portion 22 varies between 1 mm and 3 mm and the length of the slanted section 23 may vary between 0.15 mm and 1.5 mm. Furthermore, the first size B′ or diameter of the probe body 21 in circular probes may vary between 50 μm and 300 μm, whereas the diameter d of the contact tip 25, which is also substantially circular in shape, may vary between 8 μm and 80 μm.

In an exemplary embodiment, the value of the first size B of the reduced portion 26 varies between 25 μm and 200 μm and the value of the second size H of the reduced portion 26 varies between 50 μm and 400 μm, whereas the first size B′ of the section of the probe body 21 not comprising the reduced portion 26 may vary between 50 μm and 300 μm.

Advantageously, according to an embodiment of the disclosure, the contact tip 25 may also have a contact portion, which is suitably corrugated, in order to abut against a covering layer or film (oxide or dirt in general) overlaying the contact pad of the device under test.

Advantageously, in this way, according to an embodiment of the disclosure, the contact tip 25 “sticks” at the impact area on the contact pad, limiting the scrubbing action by the same tip, wherein the probe 20 presses in contact against the contact pad, which has traveled vertically, by a distance called overtravel OT.

The hook-shaped end portion 22 of the cantilever contact probe 20 according to an embodiment of the disclosure therefore deforms during such pressing contact against the contact pad, wherein its horizontal movement or scrub against the same pad is limited by the corrugated contact portion being stuck on the covering layer of the contact pads.

It is also to be noted that such sticking action is eased by the reduced portion 26 provided in the probe body 21, which improves the flexibility of the probe. By using cantilever contact probes 20 according to an embodiment of the disclosure, scrub marks are therefore reduced with respect to the probes according to the prior art.

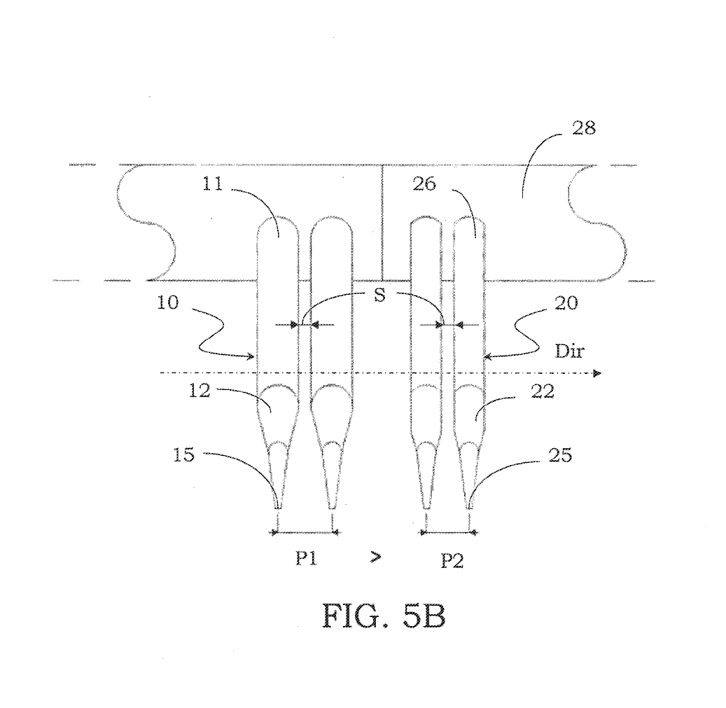

A testing head according to an embodiment of the disclosure is schematically and partially shown in FIG. 5A, globally labeled as 30. In particular, the testing head 30 comprises a ring support 27 made of aluminum, ceramics or other suitable material to which a further resin support 28 is jointly coupled, able to include a plurality of cantilever contact probes 20, in order for the same to be aligned on a same level, considered as the level or height at which the cantilever contact probes 20 exit from the further resin support 28 with respect to a ideal plane formed by the device under test, when the testing head 30 is pressing in contact against the same.

In the embodiment shown in FIG. 5A, the cantilever contact probes 20 are included in the further resin support 28 at their corresponding reduced portions 26, which are provided, as in the example shown in FIG. 4A, on the probe body 21.

It is therefore clear that in the testing head 30, the cantilever contact probes 20 may be more narrowly spaced in the further resin support 28, with respect to cantilever contact probes 10 made according to prior art, due to the reduced size precisely in the side by side direction of the probes Dir, in particular the first size B of the first area A1 at the reduced portion 26.

A testing head 30 can therefore be provided which is able to test devices having a reduced pitch with respect to those that may be tested by a traditional testing head of the prior art.

In order to completely appreciate the advantageous characteristics of the testing head 30 comprising cantilever contact probes 20 according to an embodiment of the disclosure, one may refer to FIG. 5B, where, in the left portion, a pair of cantilever contact probes 10 made according to the prior art is shown, which are placed side by side and contiguous to each other along the direction Dir, having a substantially circular cross section, whereas the portion on the right shows a pair of cantilever contact probes 20 made according to an embodiment of the disclosure, which are similarly placed side by side and contiguous to each other, at their reduced portions 26.

It is readily understood that distance P1 between the contact tips 15 of cantilever contact probes 10 according to prior art is greater than distance P2 between the contact tips 25 of the cantilever contact probes 20 according to an embodiment of the disclosure, having both the same safety distance S between probes. In this way, the cantilever contact probes 20 are able to contact pads, whose distance between centers, or pitch, is less than the pitch of the cantilever contact probes 10 of the known type (P2<P1).

It is also possible to ascertain that the testing head 30 according to an embodiment of the disclosure allows the testing of devices having contact pads of extremely reduced size.

In fact, it is to be noted that the reduction of the first size B of the first area A1 of the reduced portion 26 of the probe body 21 allows an improvement of the elastic behavior of the cantilever contact probe 20 according to an embodiment of the disclosure, with reference to its deformation during testing, i.e. during the pressing contact of the contact tip 25 of the cantilever contact probe 20 against a contact pad of the device under test.

Advantageously, according to an embodiment of the disclosure, due to its corrugated contact portion, the contact tip 25 of the cantilever contact probe 20 in any case removes the covering film from the contact pad, on which it is stuck, ensuring a proper electrical contact of the probe 20 and hence a proper functioning of the testing head 30 comprising the same. The provision of the corrugated portion of the contact tip 25 also allows a reduction of the sliding movement of the contact tip 25 over the contact pad and therefore, as already said, the length of the scrub marks.

Summarizing, it is evident that, in the case of probe bodies 21 having the same size, the testing head according to an embodiment of the disclosure allows testing of devices having reduced pitch and small pads, ensuring high quality and reliability. New specifications imposed by new technologies, with reference to the more and more reduced sizes of the contact pads and pitch, are therefore met.

Since, due to the reduction of the scrub marks, the size of contact pads may be reduced, the testing head 30 also allows a great area saving for each device, and a greater number of devices fits on the same silicon area.

Finally, due to the configuration of the cantilever contact probes 20, a testing head 30 may be provided which has a lower number of levels with respect to those used in the prior art for testing the same device, wherein each level of cantilever contact probes 20 may contact a higher number of contact pads, thanks to the reduced distance between the respective contact tips 25.

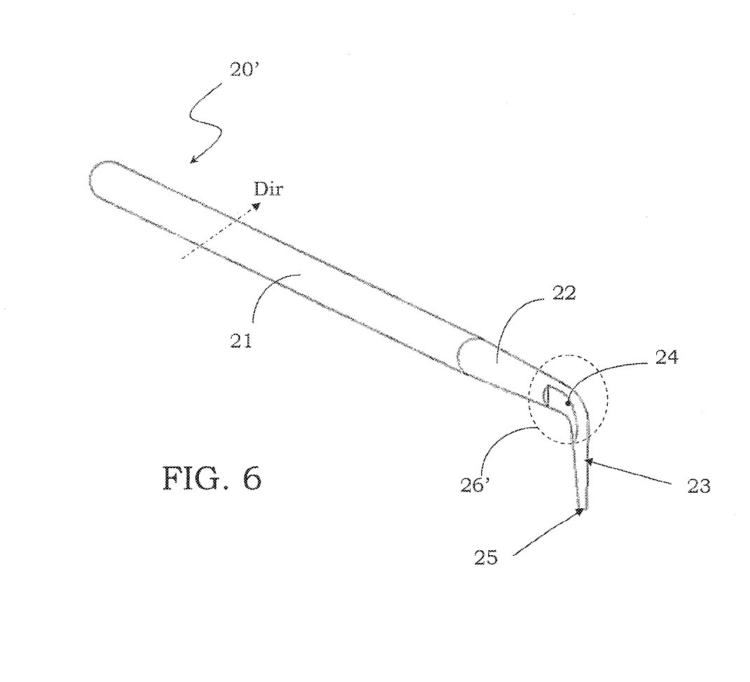

According to an alternative embodiment, a cantilever contact probe 20′ comprises a reduced portion 26′ at its end portion 22, as schematically shown in FIG. 6. In particular, the reduced portion 26′ is provided at the bending point 24 of the end portion 22, in a substantially symmetrical arrangement with respect to such bending point 24.

As previously shown, the reduced portion 26′ may be manufactured by suitable working of the cantilever contact probe 20, for example by means of symmetrical material removal with respect to the longitudinal extension axis of the cantilever contact probe 20′, from a section of the end portion 22, for example a section symmetrically positioned on the bending point 24, in order to provide a sort of symmetrical recess in said section.

Similarly to the embodiment of FIG. 5A, the reduced portion 26′ has a first area being similar to the area A1 as shown in FIG. 4B, taken in correspondence of the bending point 24 with a first size B, in particular, a maximum size in the side by side direction of the probes Dir, and a second size H, in particular, a maximum size in a direction perpendicular to the side by side direction of the probes Dir.

The cantilever contact probe 20′ also has a second area A2 as the one shown in FIG. 4C, taken in correspondence of a end portion 22, where the reduced portion 26′ is absent, having a first size B′ in the side by side direction of the probes Dir being greater that the first size A1 taken in correspondence of the reduced portion 26′; in particular, the area A2 may have a circular shape with a diameter equal to the first size B′.

Advantageously, according to an embodiment of the disclosure, the first size B of the first area A1, taken in correspondence of the reduced portion 26, is smaller than the first size B′ of the second area A2, taken in correspondence of the section of the probe body 21 lacking the reduced portion 26, along the same side by side direction of the probes Dir, and transversally with respect to the probe body 21. In a preferred embodiment, the second area A2 has a circular shape with a diameter B′, and the second size H of the first area A1 is equal to said diameter B′.

Similarly to the preceding embodiment, the first size B of the first area A1 of the reduced portion 26′ is up to 20% of the first size B′ of the second area A2 along the same side by side direction of the probes Dir. In general, the ratio between the first size B and second size H is chosen between 0.30 and 0.95.

The hook-shaped end portion 22 of each cantilever contact probe 20, in particular its slanted section 23, ends with a contact tip 25, whose diameter is substantially equal to the known probes' one, wherein said tip is such as to abut and contact against a plurality of contact pads of the device under test.

Also according to this second embodiment, the provision of the reduced portion 26′ in the end portion 22 improves the elastic properties of such end portion 22 and of the cantilever contact probe 20 as a whole, also allowing a reduction of the length of the slanted sections 23.

In the probe according to this alternative embodiment, in particular with reference to its length and the length of its individual portions, dimensional values equal to those of the probe as previously described and shown in FIG. 4A are presumed.

In an exemplary embodiment, the value of the first size B of the reduced portion 26′ varies between 20 μm and 180 μm and the value of the second size H of the reduced portion 26′ varies between 50 μm and 400 μm, whereas the first size B′ of the section of the end portion 22 not comprising the reduced portion 26′ may vary between 30 μm and 200 μm.

The contact tip 25 may also comprise a contact portion suitably corrugated, such as to abut against a covering layer or film (oxide or dirt in general), overlaying the contact pad of the device under test, so that the contact tip 25 is able to “stick” at the impact zone on the contact pad, limiting the scrub and, as previously indicated, forming smaller scrub marks.

In this case, too, the sticking action is facilitated by the provision of the reduced portion 26′ in the hook-shaped end portion 22, with an improved elastic behavior during testing.

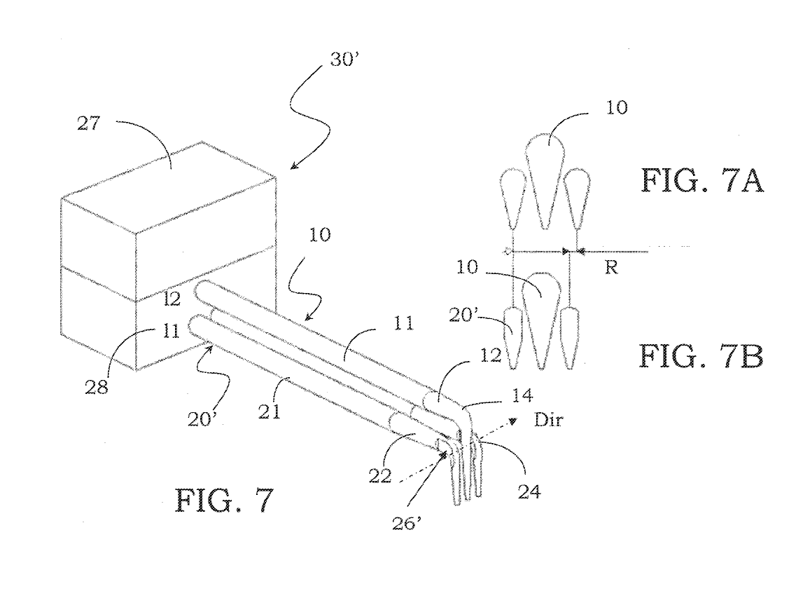

Such alternative embodiment is particularly advantageous in case of positioning the cantilever contact probes on multiple levels, as schematically shown in FIGS. 7, 7A and 7B.

In particular, FIG. 7 schematically shows a testing head 30′ comprising cantilever contact probes on at least two levels, 11 and 12.

As previously shown, the testing head 30′ comprises a ring support 27, made of aluminum, ceramics or other suitable material, to which a further resin support 28 is solidly joined, such as to include a first plurality of cantilever contact probes 20 aligned on a first level 11, as well as a second plurality of cantilever contact probes aligned on a second level 12, in particular a higher level, i.e. at a greater distance from the device under test.

It is pointed out that, advantageously, according to an embodiment of the disclosure, the cantilever contact probes at the second level 12 may be provided using cantilever contact probes without reduced portions, as those indicated by 10 in FIG. 3A. In particular, the end portions 12 of the cantilever contact probes 10 at the second level are such as to be housed without risking any contacting between the end portions 22 of the cantilever contact probes 20′ of the first level 11, due to provision of the reduced portions 26′ being realized at corresponding bending points 24 of the cantilever contact probes 20′ of the first level, indeed, with a substantial reduction of the distances between respective contact tips 25.

More in particular, based on comparison of FIGS. 7A and 7B, it is possible to confirm that the two level configuration of the testing head 30′ comprising a first level 11 of cantilever contact probes 20′ according to embodiment in FIG. 6 and a second level 12 of cantilever contact probes 10 of the known type (shown in FIG. 7B), is able to position the respective contact tips 25 closer with respect to the testing head only comprising known cantilever contact probes 10 (shown in FIG. 7A), with a reduction of total distance between the contact tips of the probes at the first level 11 equal to R.

It is therefore evident that also the testing head 30′ comprising at least one level 11 of cantilever contact probes 20′ according to the embodiment of FIG. 6 is such as to allow the testing of devices with smaller pitch with respect to a traditional testing head only comprising cantilever contact probes 10 of FIG. 3A.

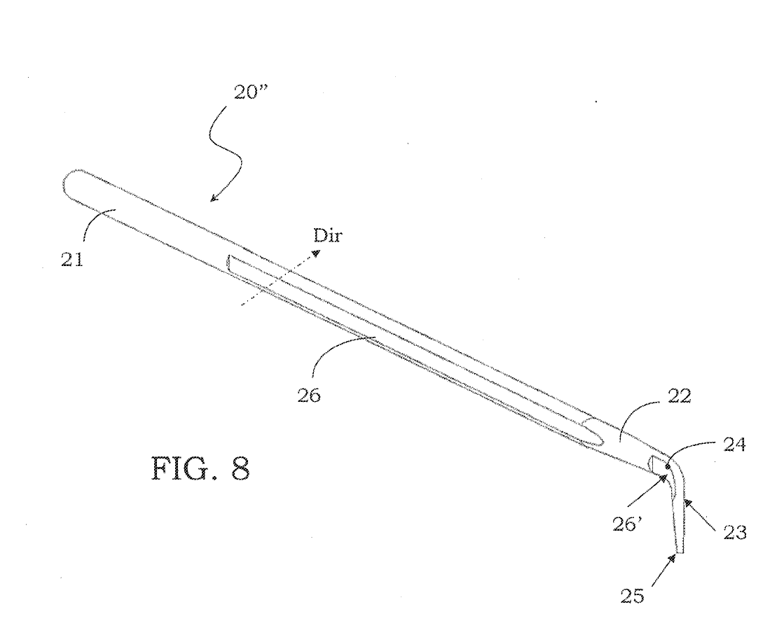

Advantageously, according to a further alternative embodiment schematically shown in FIG. 8, a cantilever contact probe 20″ may comprise a first reduced portion 26 in a section of the probe body 21 which is contiguous to the end portion 22 and a second reduced portion 26′ at an end portion 22, in particular, at a bending point 24 of the end portion 22, in a substantially symmetrical arrangement with respect to the bending point 24.

In the probe according to this further embodiment, in particular, with reference to its length and the length of the individual portions and the sizes of different areas are presumed to have dimensional values equal to those of the probes, previously described and shown in FIGS. 4A and 6.

A testing head comprising cantilever contact probes 20″ according to further embodiment of FIG. 8 clearly allow a further reduction of the distance of the respective contact tips 25, for testing devices having extremely small pitches.

In this case too, the contact tip 25 of the cantilever contact probes 20″ may have a suitably corrugated contact portion able to abut against a covering layer or film (oxide or dirt in general) overlaying the contact pad of the device under test, such as to allow testing of devices having contact pads of extremely small size.

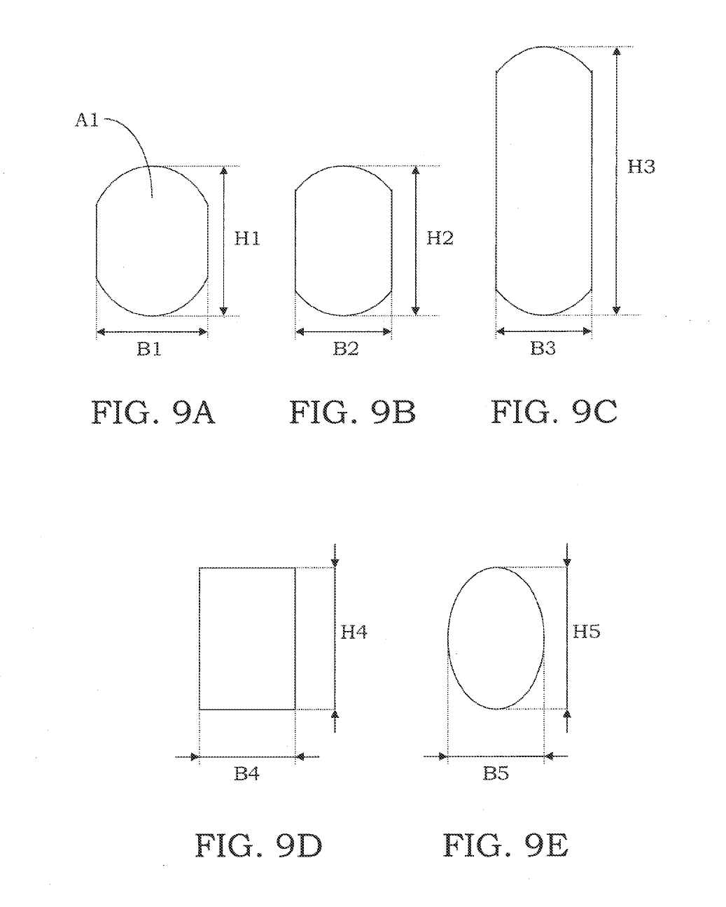

Possible areas of the reduced section of the contact probes according to an embodiment of the disclosure are shown, as non limiting examples, in FIGS. 9A to 9F.

As is shown in these figures, the areas of the reduced portions of the cantilever contact probes according to an embodiment of the disclosure may be substantially rectangular, with variable base and height, or even substantially elliptical, with variable major and minor axes.

The choice of the sections of the reduced portions may be based on different criteria:
starting with a defined pitch, based on the device under test, it is possible to establish a value of the first size B, sufficient to ensure a lack of contact between adjacent and contiguous probes;
based on the current capacity enabled by a defined test, it is possible to establish a value of the second size H, also based on the value already determined for the first size B.

In particular, as shown in FIG. 9A, a cantilever contact probe, for example a probe 20 as shown in FIG. 4A, may have a first size B1 of its first area A1 at its reduced portion 26, sufficient to contact a device having a first pitch P1.

In case of testing a device having a second pitch P2 smaller than the first pitch P1, it is possible to use a cantilever contact probe 20 with a reduced portion 26 with a first further reduced size B2 of its area A1, as shown in FIG. 9B, being B1>B2 and H1=H2.

Furthermore, if the value of the first size B3 of the section of the cantilever contact probe 20 at its reduced portion 26 is sufficient to ensure the proper pitch for the device under test, it may be desirable to perform a test with a higher current. In this case, a cantilever contact probe 20 having a higher current capacity may be provided, increasing the second size H3, as shown in FIG. 9C, being B3=B2 and H3>H2.

The areas shown in FIGS. 9A-9C have two opposed rectilinear sides and two opposed curvilinear sides. It is also possible to use cantilever contact probes 20 having reduced portions 26 with a rectangular cross section, as shown in FIG. 9D or elliptical cross section, as shown in FIG. 9E, being B4=B5 and H4=H5. Moreover, the reduced portion 26 may also have a square section, with a side shorter than the diameter of the probe body portion 21, respectively of the end portion 22, not comprising the reduced portion 26, respectively 26′.

Similar considerations may also be made for the probes 20′ and 20″ of FIGS. 6 and 8, respectively, and for the respective reduced portions 26, 26′.

Other and different embodiments of the reduced portions 26 of the cantilever contact probe 20 may also be taken into account.

It is also noted that the value of the sizes B and H of the reduced portion 26 of the cantilever contact probes 20 may also be modified for controlling the contact force or for increasing their balancing in case probes with hooks of different length have to be used, or if it is necessary to contact pads inside the device, as is the case of last generations of integrated devices comprising contact pads which are provided also inside the device, in addition to its periphery.

Summarizing, the testing head comprising cantilever contact probes according to the different embodiments as shown allows:
a reduction of the number of levels at which the probes are positioned, with a corresponding balancing of forces and improved uniformity of the scrub action over the contact pads;
an increase of the length of the hooks of the contact probes positioned on a reduced number of levels, therefore increasing the working life of the testing head, which is tied to the wear of the hooks, indeed;
an increase of probe's diameter, without the risk of mutual collision between the same, therefore improving the current capacity of the probes;
a reduction of the length of the scrub marks, at a same overtravel;
a reduction of the usable pitch value;
a reduction of the size of the contactable contact pads;
an increase of the distance between the probes, therefore obtaining an easier and more reliable manufacturing of the testing head as a whole.

More in particular, the provision of the reduced portion 26 allows different and important advantages, among which are the following:
improving the balance of forces, which may be regulated by varying the first size of the reduced portion 26, 26′, in particular, the depth of the groove on the probe body 21, as a function of the length of the slanted hook-shaped section 23, which characterizes various levels of probes;
improving the balance of forces, when the device under test has various internal pads,
improving the uniformity of the scrubs obtained on the pads by controlling the respective scrub's length up to almost eliminating the same (when the scrub mark is slightly larger than the size of the contact tip of the probe, the removal of the dirt layer on the pad and therefore a proper electrical connection being obtained due to sticking of the contact tip on the same pad).
possible increase of the current capacity of the probe, due to a suitable increase of the second size H of the probe body 21 in a transversal direction with respect to the side by side placing direction of the probes Dir.

It is evident that the skilled in the art, in order to meet contingent and specific needs, may apply various modifications and changes to the above described contact probe and testing head, which are all included within the protection scope of the disclosure.

We claim:

1. A cantilever contact probe comprising:
a probe body;
a hook-shaped end portion ending with a slanted section and being joined to the probe body, the slanted section being configured as a hook,
the hook-shaped end portion being bent at a bending point having an inclination of the hooked slanted section with respect to a longitudinal extension axis of the probe body and the hooked slanted section ending with a contact tip,
the contact tip being able to assure a mechanical and electrical contact with a contact pad of a device under test, and
a first reduced portion having a first area with a first size smaller than a corresponding first size of a second area of the probe in a section which does not comprise the first reduced portion, along a side by side placing direction of probes within a testing head,
the first reduced portion having substantially reduced sides thus forming an area having a reduced cross size.

2. The cantilever contact probe of claim 1, wherein a ratio between the first size of the first area at the first reduced portion and the first size of the second area is in the range 0.30-0.95.

3. The cantilever contact probe of claim 1, wherein the first reduced portion is symmetrical with respect to the longitudinal extension axis of the probe.

4. The cantilever contact probe of claim 1, wherein the first area of the probe at the first reduced portion has a second size along an orthogonal direction with respect to the side by side placing direction of the probes, the second size being bigger than the first size of the first area of the first reduced portion.

5. The cantilever contact probe of claim 1, wherein the contact tip comprises a corrugated contact portion.

6. The cantilever contact probe of claim 1, wherein the first reduced portion is made in a section of the probe body adjoining the end portion.

7. The cantilever contact probe of claim 1, wherein the first reduced portion is made in a section of the end portion at the bending point.

8. The cantilever contact probe of claim 6, wherein the first reduced portion is made in a section of the probe body adjoining the end portion and the cantilever contact probe further comprises a second reduced portion made in a section of the end portion at the bending point.

9. The cantilever contact probe of claim 1, wherein a value of the first size of the first area at the reduced portion is chosen according to a value of a distance between centers of contact pads of the device under test.

10. The cantilever contact probe of claim 1, wherein the first area of the probe at the first reduced portion has a second size along an orthogonal direction with respect to the side by side placing direction of the probes, a value of the second size of the first area at the reduced portion is chosen according to a value of a current that the probe should sustain.

11. The cantilever contact probe of claim 1, wherein the first area of the probe at the first reduced portion has a second size along an orthogonal direction with respect to the side by side placing direction of the probes, and values of the first and second sizes of the first area at the reduced portion are chosen to control a contact force of the probe onto the contact pad of the device under test or to balance probes having slanted sections of different length or to contact pads internal to the device under test.

12. The cantilever contact probe of claim 1, wherein the first area of the reduced portion has a shape chosen between a substantially quadrilateral figure which comprises two opposed rectilinear sides and two opposed curvilinear sides, a rectangle, a square, and an ellipse.

13. A testing head comprising:
a ring support;
a resin support coupled to the ring support; and
a plurality of cantilever contact probes supported by at least one of the ring support and resin support, each of the cantilever contact probes comprising:
a probe body;
a hook-shaped end portion ending with a slanted section and being joined to the probe body, the slanted section being configured as a hook,
the hook-shaped end portion being bent at a bending point having an inclination of the hooked slanted section with respect to a longitudinal extension axis of the probe body and the hooked slanted section ending with a contact tip,
the contact tip being able to assure a mechanical and electrical contact with a contact pad of a device under test, and
a first reduced portion having a first area with at least a first size smaller than a corresponding first size of a second area of the probe in a section which does not comprise the first reduced portion, along a side by side placing direction of the probes within a testing head,
the first reduced portion having substantially reduced sides thus forming an area having a reduced cross size.

14. The testing head of claim 13, wherein the first area of each of the cantilever contact probes at the first reduced portion has a second size along an orthogonal direction with respect to the side by side placing direction of the probes, the second size being bigger than the first size of the first area of the first reduced portion.

15. The testing head of claim 13, wherein the contact tip of each of the cantilever contact probes comprises a corrugated contact portion.

16. The testing head of claim 13, wherein the first area of the reduced portion of each of the cantilever contact probes has a shape chosen between a substantially quadrilateral figure which comprises two opposed rectilinear sides and two opposed curvilinear sides, a rectangle, a square, an ellipse.

17. The testing head of claim 13, wherein reduced portion of each of the plurality of contact probes is realized in a section of the end portion at the bending point and the plurality of contact probes are at least part of a first level of contact probes, the testing head including a second level of contact probes that are devoid of reduced portions.

18. A cantilever contact probe comprising:
a probe body;
a hook-shaped end portion ending with a slanted section and being joined to the probe body, the slanted section being configured as a hook,
the hook-shaped end portion being bent at a bending point having a suitable inclination of the hooked slanted section with respect to a longitudinal extension axis of the probe and the hooked slanted section ending with a contact tip,
the contact tip being able to assure a mechanical and electrical contact with a contact pad of a device under test, and
a reduced portion having a first area with a first size along a side by side placing direction of the probes within a testing head, and a second size, the first size being smaller than a corresponding first size of a second area of the probe in a section which does not comprise the reduced portion, the second size being equal to a corresponding second size of the second area,
the reduced portion having substantially reduced sides thus forming an area having a reduced cross size.

19. The cantilever contact probe of claim 18, wherein a ratio between the first size of the first area at the reduced portion and the first size of the second area is in the range 0.30-0.95.

20. The cantilever contact probe of claim 18, wherein the contact tip comprises a corrugated contact portion.

21. The cantilever contact probe of claim 18, wherein value of the first size of the first area at the reduced portion is chosen according to a value of a distance between centers of contact pads of the device under test.

22. The cantilever contact probe of claim 18, wherein a value of the second size of the first area at the reduced portion is chosen according to a value of a current that the probe should sustain.

23. The cantilever contact probe of claim 18, wherein values of the first and second sizes of the first area at the reduced portion are chosen to control the contact force of the probe onto the contact pad of the device under test or to balance probes having slanted sections of different length or to contact pads that are internal to the device under test.

24. A contact element comprising:
a body;
a hook-shaped end portion ending with a slanted section and being joined to the body, the slanted section being configured as a hook,
the hook-shaped end portion being bent at a bending point having an inclination of the hooked slanted section with respect to a longitudinal extension axis of the contact element and the hooked slanted section ending with a contact tip, and
a reduced portion having a first area with a first size smaller than a corresponding first size of a second area of the probe in a section which does not comprise the reduced portion, along a side by side placing direction of the contact element,
the reduced portion having substantially reduced sides thus forming an area having a reduced cross size.

25. The contact element of claim 24, wherein a ratio between the first size of the first area at the reduced portion and the first size of the second area is in the range 0.30-0.95.

26. The contact element of claim 24, wherein the reduced portion is symmetrical with respect to the longitudinal extension axis of the contact element.

27. The contact element of claim 24, wherein the first area of the contact element at the reduced portion has a second size along an orthogonal direction with respect to the side by side placing direction of the contact element, the second size being bigger than the first size of the first area of the contact element at the reduced portion.

28. The contact element of claim 24, wherein the contact tip comprises a corrugated contact portion.
